(19) United States
(12) Patent Application Publication
(10) Pub. No.: US 2009/0224639 A1
(43) Pub. Date: Sep. 10, 2009

(54) Enclosure for Electronic Equipment

(75) Inventor: Andrew W. Sosin, Addison, IL (US)

Correspondence Address: BANNER & WITCOFF, LTD., TEN SOUTH WACKER DRIVE, SUITE 3000, CHICAGO, IL, 60606, US

(73) Assignee: Telco Technologies, Inc., Addison, IL (US)

(21) Appl. No.: 12/396,862

(22) Filed: Mar. 3, 2009

Related U.S. Application Data
(60) Provisional application No. 61/034,836, filed on Mar. 7, 2008.

(51) Int. Cl. A47B 81/00; H05K 5/02

(52) U.S. Cl. 312/223.1; 361/727

(57) ABSTRACT

A climate controlled enclosure for the outdoor housing of electronic equipment provides a sealed environment, various climate control features, alarms and intrusion detection equipment. The enclosure or cabinet further includes a system of sliding shelves which enable removal of electronic equipment through the front entry doors of the cabinet. A cable support assembly is provided at the rear side or back side of each slidable shelf to support cables that are attachable to electronic equipment on the sliding shelves.

### CROSS REFERENCE TO RELATED APPLICATION

This application is a utility application based on provisional application Ser. No. 61/034,836 filed Mar. 7, 2008 entitled “Enclosure for Electronics Equipment” for which priority is claimed.

### BACKGROUND OF THE INVENTION

In a principal aspect the present invention relates to enclosures for housing electronic equipment. More specifically, the invention relates to a high-security weatherproof enclosure for outdoor containment and protection of electronic equipment wherein the enclosure is designed for housing equipment used in cellular phone and digital transmission technology

In U.S. Pat. No. 5,801,632, issued Sep. 1, 1998 entitled “Climate Controlled Outdoor Enclosure” there is disclosed a tamperproof high-security weatherproof enclosure for protection of electronic equipment, particularly equipment utilized in the cellular phone industry. That patent is incorporated in its entirety in the present specification as background material and as disclosing an enclosure which is especially adapted for providing an environment for electronic equipment associated with microcells.

Briefly, in the cellular phone and digital transmission industry, it is commonplace to provide multiple microcells for the wireless transmission of cellular phone transmissions, particularly in an urban area. This approach to cellular phone technology enables the placement of multiple microcells throughout an urban environment in particular, and to further provide that such microcells are conveniently hidden throughout a community in a manner where they will occupy a minimum space and be unobtrusive. A desirable feature of the cabinetry or enclosures associated with microcells is the size of their footprint, or in other words, the amount of space which they occupy. Miniaturization of such enclosures or cabinets is highly desired in order provide access to additional places for the placement of such enclosures. Such enclosures are typically climate-controlled environments, wherein the electronic equipment maintained therein is subject to rigorous temperature, air and humidity control, and further, wherein the environment is a highly-secure environment. Additionally, such equipment typically includes alarm functions to enable service providers to identify microcells which need service attention.

Heretofore, equipment of the type depicted in U.S. Pat. No. 5,801,632 has been highly accepted in the telecommunications industry. The protected environment for the electronic equipment maintained within the enclosure and the high security aspect of the equipment was deemed to be very appropriate and desired in that industry.

A problem that has developed, however, with respect to such enclosures or cabinets, is associated with the servicing of the electronic components maintained within those enclosures. Typically, the cables for power and for other purposes are connected into the interior of the cabinets or enclosures. The electronic components within the cabinets are physically connected to such cables and the cables within the enclosure connect the electronic components to one another. Servicing of such components often require opening the front access door to such an enclosure and that various panels associated with the other sides of the enclosure would necessarily be removable in order to gain access to cable connections. These requirements often result in a cabinet or enclosure which is sized in a manner that precludes its use in certain physical situations. Moreover, such access requirements often preclude the use of the enclosure or cabinet in physical sites where access would be limited. Thus there has developed the need for improvements in the design of such enclosures to enhance the accessibility and serviceability of the components maintained within such cabinets or enclosures. Needs of this nature led to the development of the present invention.

### SUMMARY OF THE INVENTION

Briefly, the present invention comprises a climate controlled outdoor equipment cabinet or enclosure having features of the type taught in U.S. Pat. No. 5,801,632, coupled with additional features enhancing the serviceability and accessibility to electronic components maintained within the enclosure or cabinet. More specifically, the cabinet or enclosure includes shelf components which are slidable forwardly from the interior of the cabinet or enclosure and outwardly through the front door or doors of the cabinet or enclosure. Sliding shelves support electronic components thereon, which may be accessed for service and/or replacement more easily by sliding the support shelves forwardly from the enclosure and outwardly through the front entry door to the enclosure. Additionally, there is associated with each of the sliding shelves, an artiated cable support system, comprising articulated arms which are connected or hinged to the interior of the cabinet and which may articulate to extend forwardly from the interior of the cabinet as the shelves are pulled or removed forwardly from the cabinet. The articulated arms comprise carriers for flexible cables coupled to the electronic components and enable those cables to be guided between a storage position within the cabinet where they are folded in a convenient fashion to an extended position as the shelves are moved forward enabling the cables to conveniently unfold in a controlled manner as the components to which the cables are attached are moved in concert with the sliding shelves. As a consequence, the electronic components within the enclosure or cabinet may be moved forwardly and effectively removed from the cabinet with the cables attached thereto being accessible from the front entry side of the cabinet for connection or disconnection and to permit servicing of the electronic components.

Additional features are also associated with the design of the cabinet or enclosure, such as a foldable shelf or computer support platform, which enables a service person to place their computer upon the shelf to facilitate servicing of the electronic components using the computer as a test module.

Thus, it is an object of the invention to provide a climate controlled outdoor enclosure especially useful for microcell technology installations.

It is a further object of the invention to provide a enclosure or cabinet design for electronic components and equipment wherein the components and electronic equipment is accessible from a front entry door and may be serviced and/or replaced by movement into and out of that front entry door.

Yet another object of the invention is to provide a climate controlled outdoor enclosure wherein the interior of the enclosure incorporates a cable management system which enables connection of multiple cables to electronic components on movable shelves within the enclosure. The cable management system is designed to permit movement of the electronic equipment forwardly through the front entry door of the enclosure by permitted extension of folded or articulated cable supported on articulated arms.

Yet another object of the invention is to provide a climate controlled outdoor enclosure which enables the servicing of components through the front entry door thereof and enables utilization and placement of the enclosure in sites that otherwise may not be available for such enclosure placement.

Another object of the invention is to provide a climate controlled outdoor enclosure which enables the use of an enclosure having a minimum footprint or size for electronic components to thereby enable the enclosure to be used in additional otherwise unusable locations.

These and other object, advantages and features of the invention would be set forth in the following description.

### BRIEF DESCRIPTION OF THE DRAWING

In the detailed description which follows, reference will be made to the drawing comprised of the following figures:

FIG. 1 is an isometric (photographic) view of an embodiment of the invention having first and second front doors;

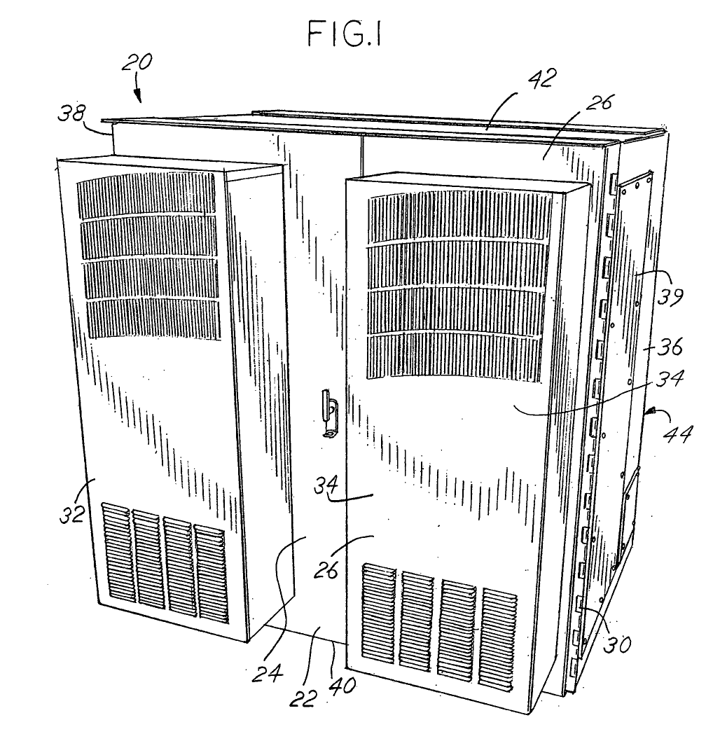

FIG. 2 is an isometric (photographic) view of the embodiment of FIG. 1, wherein the front doors of the enclosure are open;

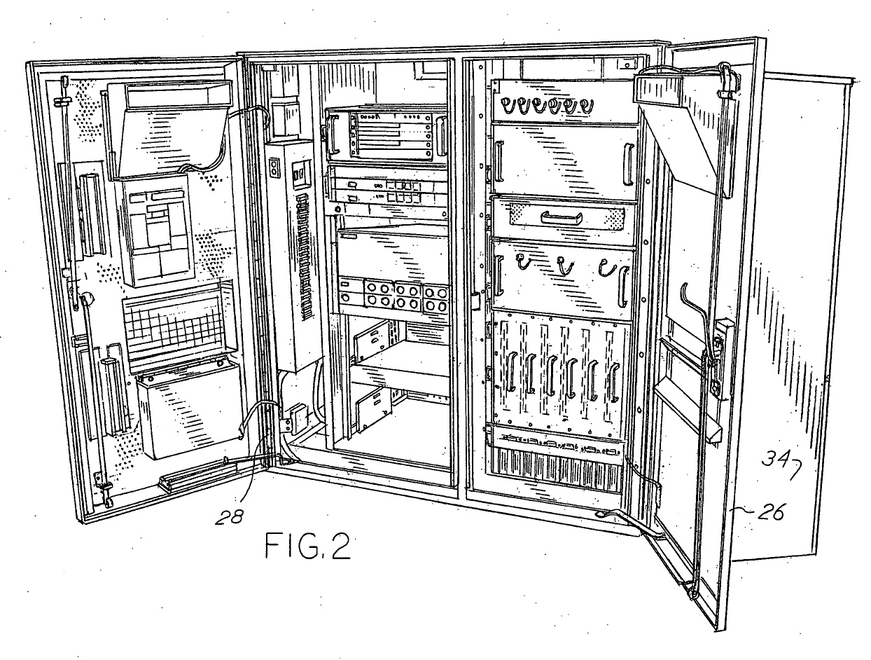

FIG. 3 is a further isometric (photographic) view of the embodiment of FIG. 1, wherein the doors are open and the various sliding shelves of the enclosure are exposed;

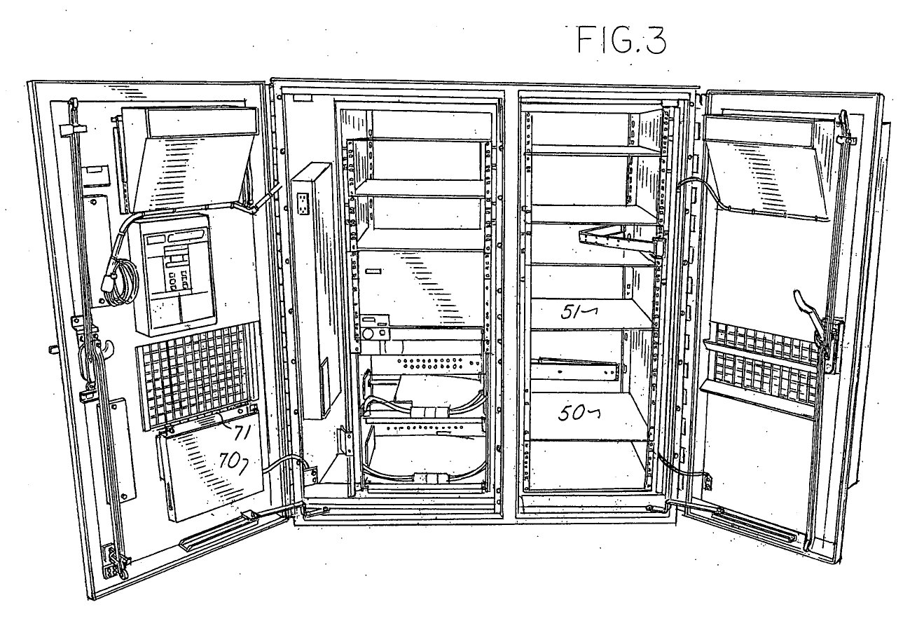

FIG. 4 is an isometric (photographic) view of the embodiment of FIG. 1, wherein the front doors of the enclosure are open and various shelves within the enclosure have been extended to an open position;

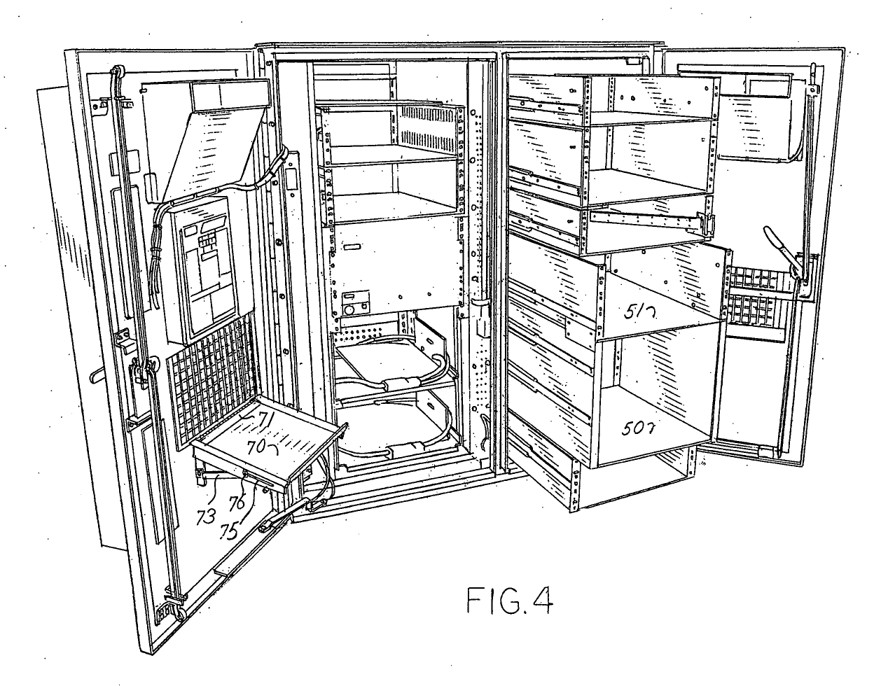

FIG. 5 is an isometric (photographic) view of the enclosure of FIG. 1, wherein a back panel thereof has been removed to reveal the articulated arms and sliding shelves incorporated in the enclosure of the invention;

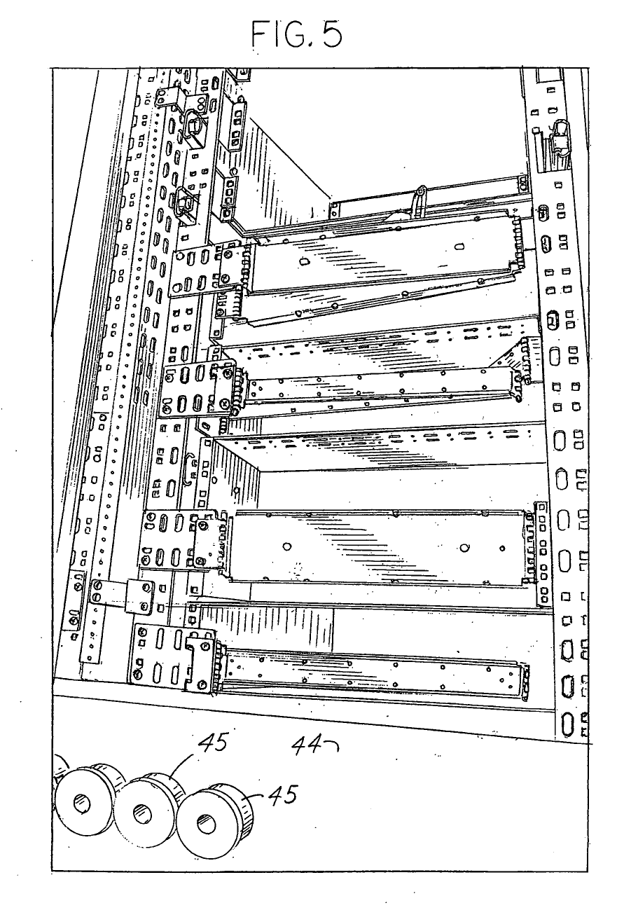

FIG. 6 is an isometric (photographic) view of the enclosure of FIG. 1, wherein a back side panel has been removed and the articulated arms are depicted without shelving;

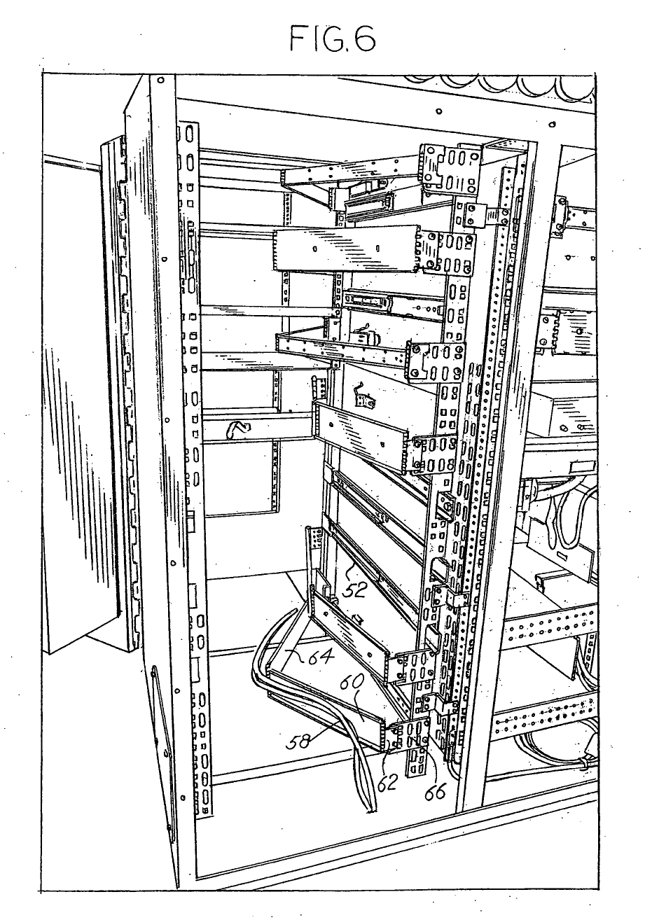

FIG. 7 is a further isometric (photographic) view of the enclosure of FIG. 1 as viewed from the backside of the enclosure;

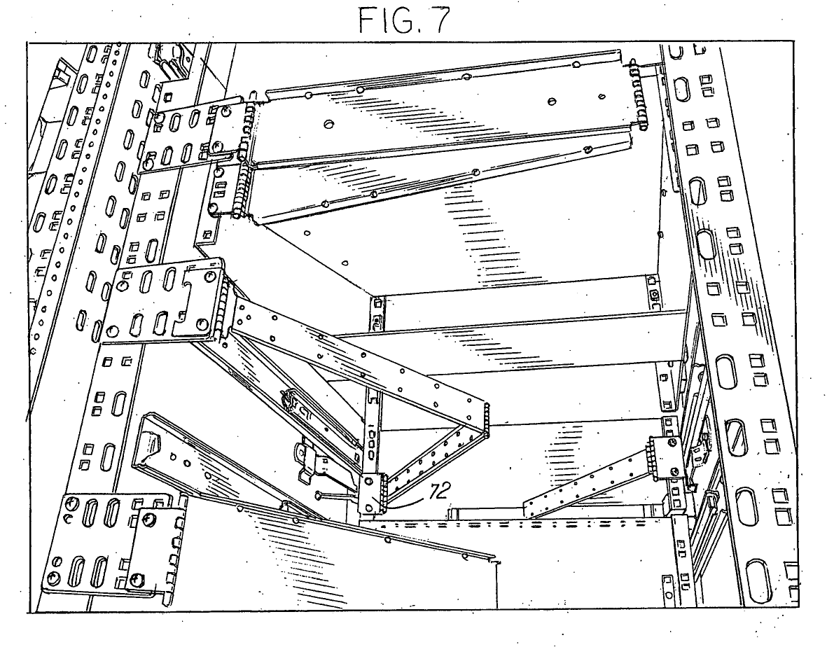

FIG. 8 is an isometric (photographic) view of the enclosure of FIG. 1 illustrating an electronic component on a sliding shelf as viewed from the front side of the enclosure;

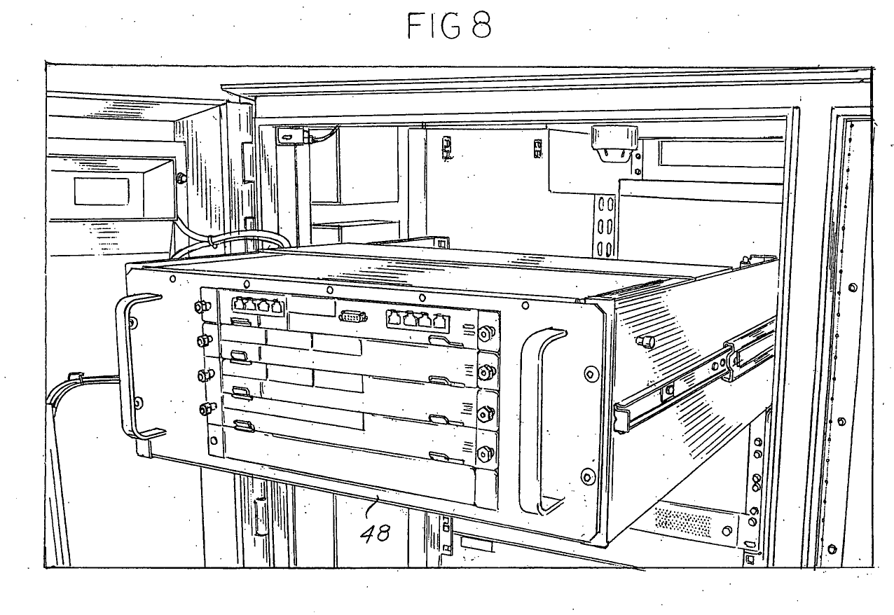

FIG. 9 is an isometric (photographic) view of the enclosure of FIG. 1 depicting an internal wall of the enclosure, the slide mechanism and a retention mechanism for maintaining a sliding shelf in a closed position;

FIG. 10 is an isometric (photographic) view of the enclosure of FIG. 1 depicting a lateral side of a sliding shelf with a pin or post or stud which is engaged by a retention member when the shelf is in the closed position;

FIG. 11 is a front isometric (photographic) view of the enclosure of FIG. 1 depicting a sliding shelf, wherein a retention lever is maintained in a position for retaining the associated shelf in a closed position;

FIG. 12 is an isometric (photographic) view illustrating the manner of engaging the retention lever to disengage that lever from the shelf; and

FIG. 13 is an isometric (photographic) view depicting the release position of the retention lever so that a sliding shelf can be moved forwardly on slide from the enclosure of the embodiment of FIG. 1.

### DESCRIPTION OF AN EMBODIMENT OF THE INVENTION

The embodiment depicted includes the features for an enclosure as set forth in U.S. Pat. No. 5,801,632, which is incorporated in its entirety in the specification as an example of the features and for depiction of features of the enclosure or cabinet of the present invention. Specifically, U.S. Pat. No. 5,801,632 features a structure for an enclosure which comprises a sealed environment for electronic equipment. The enclosure includes an intrusion alarm, a high temperature alarm, and a low temperature alarm. Further, the enclosure or cabinet includes heaters and an air conditioner. The air conditioner is incorporated in the front entry door of the enclosure as is the air conditioning system associated with the enclosure or cabinet of the present invention. The enclosure further includes an arrangement for collecting condensation within the enclosure and dispelling it from the enclosure. All of these features are incorporated in a representative embodiment of the present invention.

In addition, the present invention includes other features which, in combination, and which by themselves constitute features associated with such a cabinet or enclosure believed distinct and enable the construction of an enclosure or cabinet having a highly efficient, minimum footprint relative to the amount of electronic equipment therein. Further, the additional features provide means for access to the electronic components stored within the cabinet or enclosure through the front entry doors thereof by placing such equipment on horizontal slidable storage shelves which are movable into and out of the enclosure. Cables attached to the electronic equipment are typically attached to the back side or rear side of the electronic equipment stored within the enclosure, and thus the cables are attended by a cable management system comprised of articulated arms which support the cables, enabling them to fold and move between a folded condition at the backside of the interior of the enclosure and an extended condition projecting forwardly through or to the front entry of the enclosure.

More specifically referring to the figures, the aspects of the embodiment of the present invention are depicted. Thus a cabinet or enclosure 20 includes a front side 22 or front entry side 22 having a first entry door 24 and a second front entry door 26. The first entry door 24 is support on a vertical hinge 28 and may pivot outwardly about that hinge 28 for access to the interior of the cabinet. The second entry door 26 is mounted on a vertical hinge 30, again to permit access to the interior of the cabinet. As shown in the Figures, an air conditioning system and ambient temperature control system 32 is mounted on the first door 24. A similar air conditioning system 34 is mounted on the second door 26.

The cabinet or enclosure includes opposite lateral sides 36 and 38, a bottom side 40, a top side 42 and a back side 44, defining a generally parallelepiped enclosure. When the doors 24 and 26 are in a closed position, the enclosure or cabinet is generally sealed and the interior thereof is controlled with respect to temperature, humidity and accessibility as generally taught in U.S. Pat. No. 5,801,632 by way of example.

Various removable access panels (eg. panel 39) may be incorporated in any of the side panels 36, 38, back panel 44 and the like. Such panels would typically include access ports for power cables to enter the cabinetry through entry ports (such as back side entry ports 45). The placement and the manner of attachment of such cables is known to those of skill in the art.

The remaining figures illustrate in greater detail the added features for a cabinet or enclosure of the type under consideration which enable greater accessibility for servicing and which further enable minimizing of the footprint or size of the cabinetry or enclosure. More specifically, a first sliding shelf 50 is mounted on parallel slides 52 and 54 on opposed sides within the cabinet to enable an electronic component 48 positioned on the shelf 50 to move in concert with the sliding shelf 50. Typically, the electrical component 48 mounted on the sliding shelf 50 will be connected to other components and power sources via cables such as cables 58 within the enclosure or cabinet 20.

The cables 58 are attached to or bundled with an articulated arm system comprising, in the embodiment shown, a first arm 60 hinged at a first end 62 thereof to the cabinet 20 and a second arm 64 hinged to the opposite end 68 of the first arm 58. The cables 58 are so attached or bundled and affixed to the arms 60, 64 will move with the arms 60, 64 between a retracted position, and an extended position as depicted. Thus, the articulated arms 60, 64 serve as a support for cables 58 which are bundled and attached thereto to promote the appropriate folding and thus management of the cables 58 attached to equipment components 48 and are movable or foldable between the positions illustrated of the shelves 50 and 51. Of course, multiple shelves, each associated with its own articulated arm may be incorporated in the enclosure or cabinet 20, depending upon the size of the cabinet and the size of the electrical components to be fitted therein.

The design of the articulated cable support arms 58 and 64 may be varied. The particular disclosure is directed to an arm comprised of two sections which fold with respect to one another and to which bundled cables 58 are attached. The connected arms 60, 64 are depicted as being attached at one end to a internal cabinet surface or bracket 66 supported on the internal surface and the opposite end 72 adapted to be attached to a shelf 50, 51 and located in a position adjacent to the electronic equipment or components supported on a sliding shelf 50, 51. Various other arm or cable support systems may be utilized without departing from the spirit and the scope of the invention. Additionally, the size, shape and extended movement of the various shelves 50, 51 may be adjusted or controlled or altered to conform with the necessary equipment specifications to be housed within the cabinet or enclosure.

As an additional feature of the invention, a pivotable shelf 70 is attached to the inside of the front entry door 24. The pivotable shelf 70 is designed to support a personal computer or service computer which a technician will place thereon for troubleshooting with respect to the electrical components or equipment items that may be removed, replaced or otherwise positioned by sliding out the shelves such as shelves 50 and 51.

More specifically, the pivotal shelf 70 is hinged on one edge by a hinge member to the front side wall of the front side door 24. A support link 73, pivotably connected at one end to the door 24 includes a pin 76 slidably engaged with a slot 75 in the shelf 70. The pin 76 may fit into a detent such as detent 77 to hold the shelf in angled position so that a personal computer or other diagnostic item may be supported thereby.

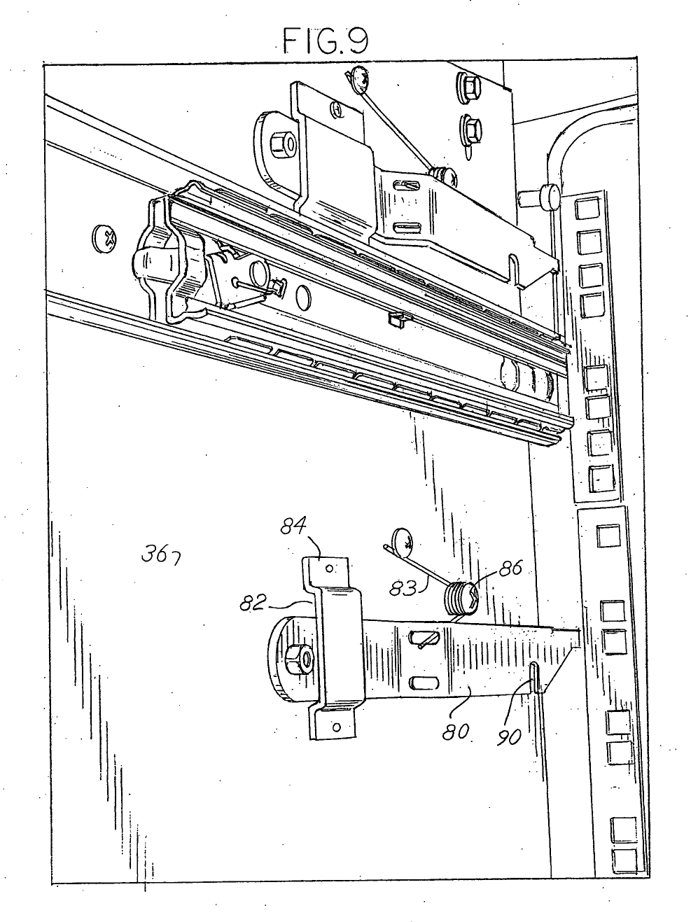

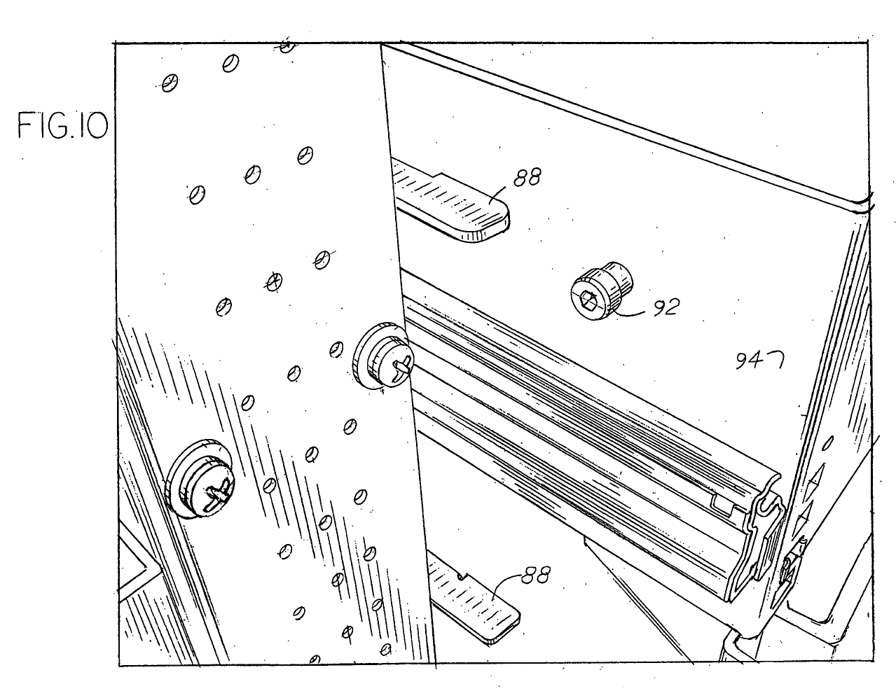

FIGS. 9 to 13 illustrate a further feature of the invention. The figures illustrate a latch mechanism which is utilized to maintain the sliding shelves, such as shelves 50 and 51 locked in position within the cabinet or enclosure 20. The latch mechanism may be released or manipulated to release the shelves 50, 51 so that they may slide forwardly for our respective slides.

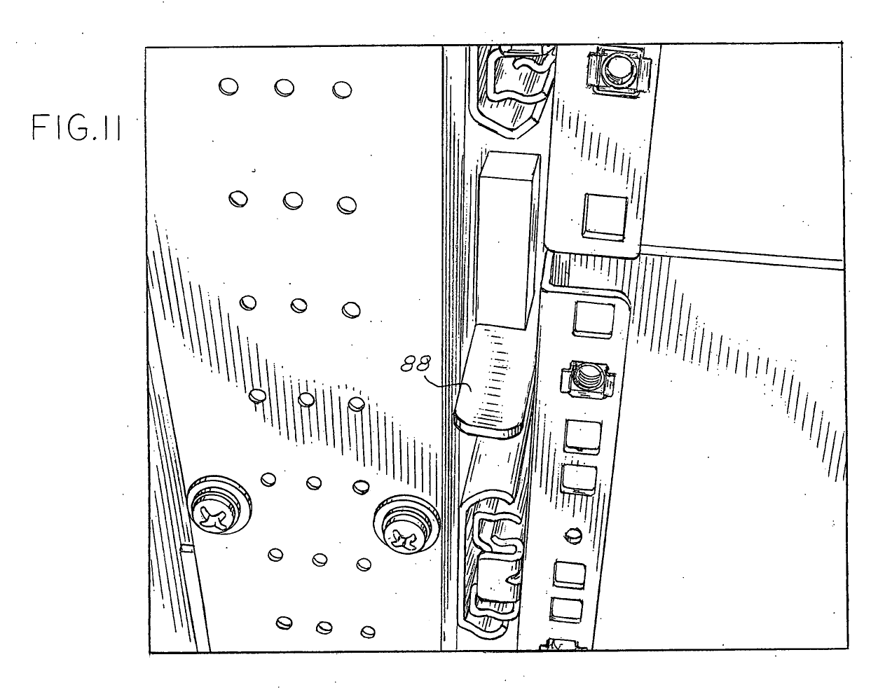

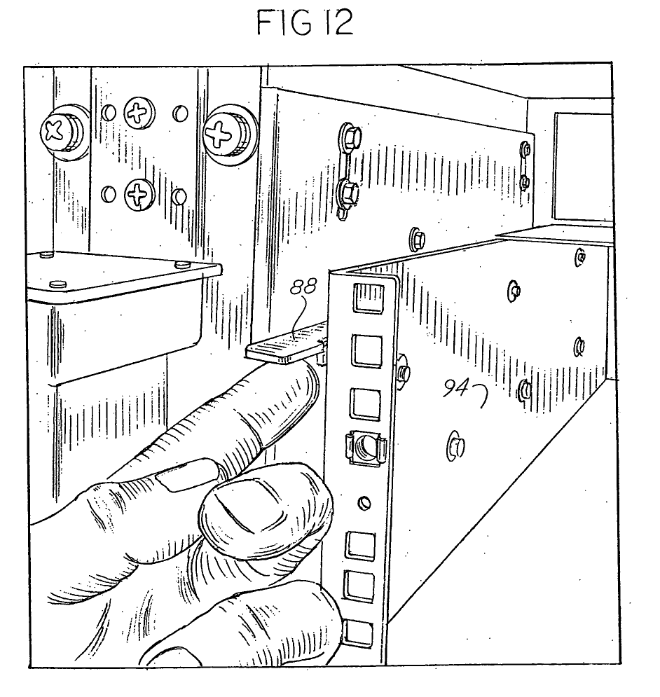

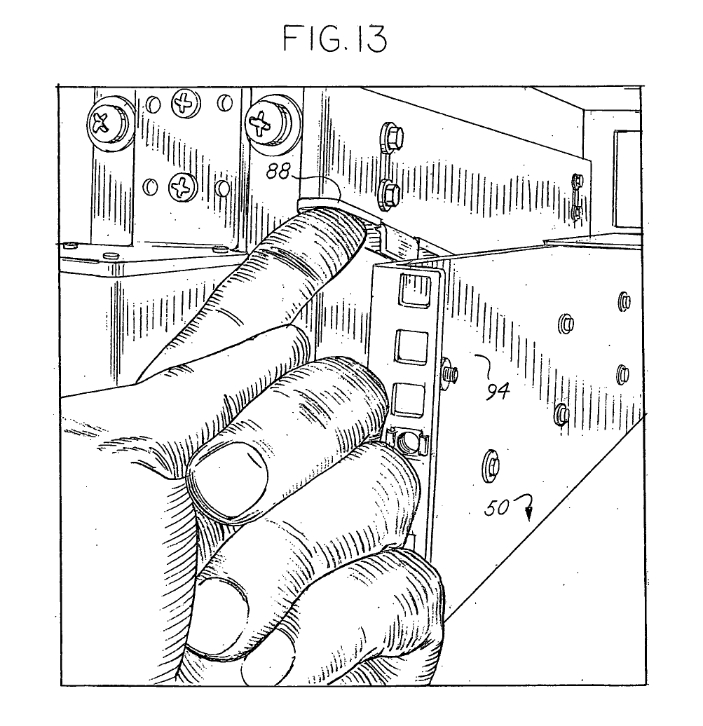

Thus, there is mounted to a side panel, such as a lateral side panel 36, a pivotal latch bar 80. The latch bar 80 is mounted in a slot 82 of a bracket 84, attached to the lateral sidewall 36. The end of the latch bar 80 nested within the bracket 84 enables the bracket 80 to move pivotally within the slot 82 defined by the bracket. The latch bar 80 is otherwise maintained in position by means of a cable or wire 83, attached at one end to the sidewall 36 fits over stud 86 and is connected at its opposite end to bar 80. The latch bar includes a free end 88, which projects forwardly between the sidewall 36 and the side of a sliding shelf 50. The free end 88 may be manipulated to pivot within the space between the lateral or sidewall of sliding shelf 50 and lateral side 36 of the cabinet 20. The lower side of the latch bar 80 includes a notch 90, which may engage a projecting pin or stud 92 projecting laterally from a sidewall 94 of shelf 50. When the latch bar 80 is in the lowered position as depicted in FIGS. 11 and 12, the notch 90 engages the pin 92 precluding the shelf 50 from sliding on the slides. Manually lifting the latch bar 80 as in FIG. 13 enables at release of the notch 90 from the pin 92, thereby enabling sliding movement of the shelf 50.

Each of the shelves of the cabinet or enclosure 20 include a similar latching mechanism. While there has been set forth a preferred embodiment of the invention, it is to be understood that the invention is to be limited only by the following claims and equivalents thereof.

What is claimed is:

1. An enclosure assembly for providing a secure and climate controlled environment for electronic equipment comprising:
a generally rectangular parallel piped cabinet defining an interior equipment enclosure, said cabinet including a back side, a bottom side, a top side, a first lateral side, a second lateral side, and a front side, said front side having at least one vertically hinged entry door, said cabinet including sealing means for precluding substantial entry of outside air when the door is closed;
said cabinet including at least one horizontal equipment support shell within said enclosure slidably mounted for movement between a first position entirely within said cabinet enclosure and a second position projecting at least in part outwardly from the front side of the cabinet enclosure when the entry door is open, said support shelf including a back side and a front side;
said cabinet enclosure further including a cable management and support mechanism at the back side of said support shelf, said support mechanism comprising an articulated arm assembly foldable between a first unextended position and a second at least partially extended position.

2. The enclosure assembly of claim 1 wherein said arm assembly comprises a first cable support arm and a second cable support arm attached to the first support arm, said first support arm hinged at one end to the cabinet and at the opposite end to the second support arm, said arms positioned to extend generally horizontally from the first unextended position toward the second at least partially extended positions.

3. The enclosure assembly of claim 1 wherein the entry door includes a temperature control system mounted thereon for control of ambient temperature within the enclosure.

4. The enclosure assembly of claim 1 further including a folding support tray mounted on the inside of the entry door.

5. The enclosure assembly of claim 1 further including one or more components selected from the group consisting of a heater; a closed loop heat exchanger; a condensation collection and removal system; an alarm system for sensing a low temperature, a high temperature or an intrusion in the enclosure; an air conditioner; and an communication system for transmitting alarm information.

6. An enclosure assembly for providing a secure and controlled environment for electronic equipment comprising:
a generally sealed storage cabinet including a front entry door and at least one horizontal shelf slidably mounted therein and slidable between a first storage position entirely within the cabinet and a second access position extending at least partially outside of the cabinet when the entry door is open, said shelf including a back side; and
an articulated cable support arm assembly mounted in the cabinet at the back side of the shelf, said arm assembly pivotally hinged to the interior of the cabinet and foldable between an extended position when the shelf is extended and a folded position when the shelf is positioned within the interior of the cabinet.
